(19) United States
(12) Patent Application Publication
(10) Pub. No.: US 2022/0109005 A1
(43) Pub. Date: Apr. 7, 2022

(54) ARRAY SUBSTRATE AND DISPLAY DEVICE THEREOF

(71) Applicant: SHENZHEN CHINA STAR OPTOELECTRONICS SEMICONDUCTOR DISPLAY TECHNOLOGY CO., LTD., Shenzhen, Guangdong (CN)

(72) Inventor: Junzheng Liu, Shenzhen (CN)

(21) Appl. No.: 16/764,200

(22) PCT Filed: Apr. 22, 2020
(86) PCT No.: PCT/CN2020/086157

§ 371 Date: May 14, 2020

(30) Foreign Application Priority Data
Apr. 13, 2020 (CN) 202010287607.8

(51) Int. Cl. H01L 27/12

(52) U.S. Cl. CPC H01L 27/124

(57) ABSTRACT

The application provides an array substrate and a display device thereof. The array substrate includes a substrate, a gate layer, a first signal electrode layer, an active layer, and a second signal electrode layer, which are stacked, wherein the first signal electrode layer is patterned to form a first signal electrode, the second signal electrode layer is patterned to form a second signal electrode, the first signal electrode is one of a source or a drain, and the second signal electrode is the other one of the source or the drain.

### FIELD OF INVENTION

The present application relates to the field of display, in particular to an array substrate and display device thereof.

### BACKGROUND OF INVENTION

In current touch panel technology, thin film transistors (TFTs) act as a key device for touch panel display driving, and play an important role in display effect of flat panel displays. TFTs mainly include silicon-based TFTs, organic TFTs, and oxide TFTs. In recent years, metal oxide semiconductor-based TFTs are expected to become next-generation mainstream TFT technology due to their advantages such as relatively high carrier mobility, high light transmittance, and low-temperature process. With electrical performance of oxide TFTs continuously improving, their applications are continuously expanding. However, in current metal oxide semiconductor TFT technology, an active layer channel adopts a horizontal channel structure, and a length of the horizontal channel is not easy to control. Such devices adopting horizontal channels generally have problems, such as low hole mobility, large surface leakage current, large off-state current, and high hole concentration.

Therefore, the prior art has a problem that the channel length of the active layer is not easy to control.

### Technical Problem

The present application provides an array substrate and a display device thereof, which effectively solves the problem that the channel length of the active layer is not easy to control in the prior art.

### SUMMARY OF INVENTION

In a first aspect, an embodiment of the present application provides an array substrate. The array substrate includes: a gate layer formed on the substrate and patterned to form a gate; a first signal electrode layer formed on a side of the gate away from the substrate, and patterned to form a first signal electrode; an active layer formed on a side of the first signal electrode away from the gate layer; a second signal electrode layer formed on a side of the active layer away from the first signal electrode and patterned to form a second signal electrode; wherein the first signal electrode is one of a source and a drain, and the second signal electrode is the other one of the source and the drain.

In the array substrate provided by the present application, the array substrate further includes an etching barrier layer, and the etching barrier layer is positioned between the active layer and the second signal electrode.

In the array substrate provided by the present application, a through-hole is formed in the etching barrier layer, the through-hole penetrates the etching barrier layer and forms a contact area with the active layer, and the second signal electrode is connected to the active layer in the contact area through the through-hole.

In the array substrate provided by the present application, the array substrate further includes a pixel electrode and an insulating layer, the insulating layer is disposed on a side of the etching barrier layer away from the substrate, the pixel electrode is disposed on a side of the insulating layer away from the substrate, and the pixel electrode is connected to the second signal electrode through the through-hole penetrating the insulating layer.

In the array substrate provided by the present application, an area where the pixel electrode contacts the second signal electrode covers an area where the second signal electrode contacts the active layer.

In the array substrate provided by the present application, a thickness of the second signal electrode in the area where the second signal electrode contacts the active layer is greater than a thickness of the second signal electrode in a non-contact area.

In the array substrate provided by the present application, the active layer is formed directly on a side of the first signal electrode away from the substrate.

In the array substrate provided by the present application, a film layer thickness between the first signal electrode and the second signal electrode is equal to a channel length of the active layer.

In the array substrate provided by the present application, the first signal electrode layer is also patterned to form data lines. In a second aspect, an embodiment of the present application further provides a display device. The display device includes the above-mentioned array substrate. The array substrate includes: a substrate; a gate layer formed on the substrate and patterned to form a gate; a first signal electrode layer formed on a side of the gate away from the substrate, and patterned to form a first signal electrode; an active layer formed on a side of the first signal electrode away from the gate layer; a second signal electrode layer formed on a side of the active layer away from the first signal electrode, and patterned to form a second signal electrode; wherein the first signal electrode is one of a source and a drain, and the second signal electrode is the other one of the source and the drain.

In the array substrate provided by the present application, the array substrate further includes an etching barrier layer, the etching barrier layer is positioned between the active layer and the second signal electrode.

In the array substrate provided by the present application, a through-hole is formed in the etching barrier layer, the through-hole penetrates the etching barrier layer and forms a contact area with the active layer, and the second signal electrode is connected to the active layer in the contact area through the through-hole.

In the array substrate provided by the present application, the array substrate further includes a pixel electrode and an insulating layer, the insulating layer is disposed on a side of the etching barrier layer away from the substrate, the pixel electrode is disposed on a side of the insulating layer away from the substrate, and the pixel electrode is connected to the second signal electrode through the through-hole penetrating the insulating layer.

In the array substrate provided by the present application, an area where the pixel electrode contacts the second signal electrode covers an area where the second signal electrode contacts the active layer.

In the array substrate provided by the present application, a thickness of the second signal electrode in the area where the second signal electrode contacts the active layer is greater than a thickness of the second signal electrode in a non-contact area.

In the array substrate provided by the present application, the active layer is formed directly on a side of the first signal electrode away from the substrate.

In the array substrate provided by the present application, a film layer thickness between the first signal electrode and the second signal electrode is equal to a channel length of the active layer.

In the array substrate provided by the present application, the first signal electrode layer is further patterned to form data lines.

### Beneficial Effect

The present application provides an array substrate and a display device. The array substrate includes a substrate, a gate layer, a first signal electrode layer, an active layer, and a second signal electrode layer, which are stacked, wherein the first signal electrode layer is patterned to form a first signal electrode, the second signal electrode layer is patterned to form a second signal electrode, the first signal electrode is one of a source or a drain, and the second signal electrode is the other one of the source or the drain. In this application, a two-layer structure is formed by separately forming a source and a drain, and a thickness of the film layer between the source and the drain is equal to a channel length of the active layer. By controlling the thickness of the film layer between the source and the drain, the channel length is controlled, and the yield of the array substrate is improved.

### DESCRIPTION OF DRAWINGS

FIG. 1 is a schematic cross-sectional structure diagram of an array substrate in the prior art.

FIG. 2 is a schematic cross-sectional structure diagram of an array substrate provided by an embodiment of the present application.

FIG. 3 is a schematic structural diagram of a source and drain channel provided by an embodiment of the present application.

### DETAILED DESCRIPTION OF PREFERRED EMBODIMENTS

The technical solutions in the embodiments of the present application will be described clearly and completely with reference to the drawings in the embodiments of the present application. Obviously, the described embodiments are only a part of the embodiments, but not all the embodiments. Based on the embodiments of the present application, all other embodiments obtained by those skilled in the art without making creative work fall within the protection scope of the present application.

In the description of this application, it should be understood that the orientations or positional relationships indicated by the terms “center”, “longitudinal”, “transverse”, “length”, “width”, “thickness”, “above”, “below”, “front”, “back”, “left”, “right”, “vertical”, “horizontal”, “top”, “bottom”, “inner”, “outer”, “clockwise”, “counterclockwise” etc., are based on those shown in the drawings. It is only for the convenience of describing the present application and simplifying the description, rather than indicating or implying that the device or element referred to must have a specific orientation, be constructed and operate in a specific orientation, and therefore cannot be construed as a limitation of the present application. Therefore, the directional terms are used for explaining and understanding the present invention, but not for limiting the present invention. In the drawings, similarly structured units are denoted by the same reference numerals. In addition, the terms “first” and “second” are used for descriptive purposes only, and cannot be understood as indicating or implying relative importance or implicitly indicating the number of technical features indicated. Thus, the features defined as “first” and “second” may explicitly or implicitly include one or more of the features. In the description of this application, the meaning of “plurality” is two or more, unless otherwise specifically limited.

In the description of this application, it should be noted that, unless otherwise specified and limited, the terms “installation”, “connected”, and “connection” should be understood in a broad sense. For example, it can be fixed or detachable connected, or connected integrally. It can be a mechanical connection, an electrical connection or can communicate with each other. It can be directly connected or indirectly connected through an intermediate medium. It can be the connection between two elements or the interaction between two elements. Those of ordinary skill in the art can understand the specific meanings of the above terms in this application according to specific situations.

In this application, unless otherwise clearly specified and defined, the first feature “above” or “below” the second feature may include the first feature and the second feature in direct contact, it may also include that the first feature and the second feature are not in direct contact but are in contact through another feature between them. Moreover, the first feature is “higher”, “above” and “on” the second feature includes that the first feature is directly above and obliquely above the second feature, or simply means that the first feature is higher in level than the second feature. The first feature is “lower”, “below” and “under” the second feature includes that the first feature is directly below and obliquely below the second feature, or simply means that the first feature is lower in level than the second feature.

The following disclosure provides many different embodiments or examples for implementing different structures of the present application. In order to simplify the disclosure of the present application, the components and settings in specific embodiments are described below. Certainly, they are only embodiments and are not to limit this application. Moreover, the present application may repeat reference numerals and/or reference letters in different embodiments. Such repetition is for simplicity and clarity and does not indicate the relationship between the various embodiments and/or settings discussed. In addition, the present application provides embodiments of various specific processes and materials, but those of ordinary skill in the art may consider the application of other processes and/or the use of other materials.

In view of the problem in the prior art that the channel length of the active layer is not easy to control, the present invention provides a display panel and a display device thereof to alleviate this problem.

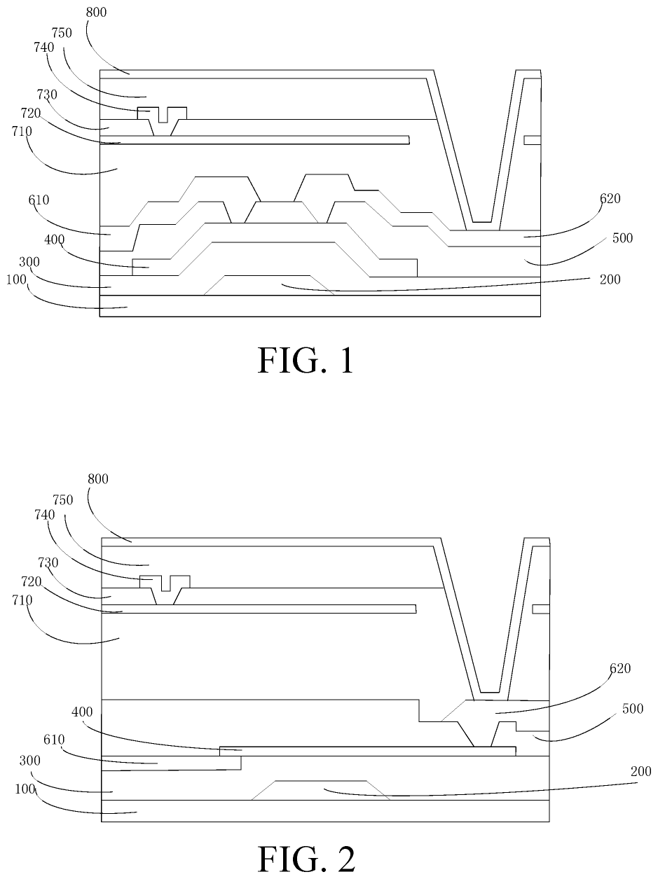

FIG. 1 is a prior art array substrate, the array substrate is deposited with a gate 200, a gate insulating layer 300, an active layer 400, a barrier etching layer 500, a source-drain layer 600, an insulating layer 700, and a pixel electrode layer 800, wherein a material of the active layer 400 is indium gallium zinc oxide, which has better conductivity than traditional polysilicon layer. After the source-drain layer 600 is formed into a film, it is etched to form a source 610 and a drain 620. Such devices adopting horizontal channels generally have problems such as low hole mobility, large surface leakage current, large off-state current, and high hole concentration, which are likely to cause adverse reactions on the substrate. In addition, the pixel electrode layer 800 needs to be connected to the drain 620 through the insulating layer 700. Since the insulating layer 700 includes a first insulating layer 710, a common electrode layer 720, a second insulating layer 730, and a touch electrode 740, the pixel electrode 800 needs to pass through multiple layers of the insulating layer, each of which has a different material and shape. This may easily cause the pixel electrode 800 to crack.

Therefore, in the prior art, there is a problem that the channel length of the active layer is not easy to control and is likely to cause adverse reactions of the panel.

FIG. 2 is an array substrate provided by this application. As shown in FIG. 2, the array substrate includes: a substrate 100; a gate layer 200 formed on the substrate 100 and patterned to form a gate; a first signal electrode layer 610 formed on a side of the gate insulating layer 300 away from the substrate 100, and patterned to form a first signal electrode; an active layer 400 formed on a side of the first signal electrode away from the gate layer; an etching barrier layer 500 formed on a side of the active layer 400 away from the substrate; and a second signal electrode layer 620 formed on a side of the active layer away from the first signal electrode and patterned to form a second signal electrode, wherein the first signal electrode 610 is one of a source or a drain, and the second signal electrode 620 is the other one of the source or the drain.

The substrate 100 is generally a flexible substrate, and a material of the substrate 100 is generally polyimide, transparent glass substrate, polyethylene terephthalate, cycloolefin copolymer, polyethersulfone resin, and the like. A material of the gate layer 200 is a metal composite material such as molybdenum and copper, or a composite layer composed of laminated molybdenum and copper, or a composite layer composed of laminated molybdenum and aluminum, or the like. The gate insulating layer 300 covers the gate layer 200 to prevent the gate layer 200 from contacting the first signal electrode 610 or the active layer 400. The first signal electrode 610 is formed on the gate insulating layer 300, which is deposited on the gate insulating layer 300 by chemical vapor deposition, vacuum evaporation, plasma chemical vapor deposition, sputtering, or low-pressure chemical vapor deposition. The first signal electrode may be a metal material such as copper, aluminum, cobalt, or a composite layer composed of molybdenum and copper, or a composite layer composed of molybdenum and aluminum. A material of the active layer 400 is indium gallium zinc oxide. Compared with the active layer formed by traditional polysilicon, the indium gallium zinc oxide has better carrier capability. In the present application, the active layer 400 is formed with a channel. A material of the etching barrier layer 500 may be silicon oxide or a stacked composite layer formed by silicon oxide and silicon nitride or a composite layer composed of three layers of silicon nitride, silicon oxide, and silicon oxynitride; or a composite layer composed of three layers of silicon nitride, silicon oxide, and aluminum oxide. The material of the etching barrier layer 500 may also be aluminum nitride, hafnium dioxide, or the like. The second signal electrode layer 620 is formed on a side of the active layer 400 away from the substrate 100. The second signal electrode layer 620 is deposited on the active layer 400 by chemical vapor deposition, vacuum evaporation, plasma chemical vapor deposition, sputtering, or low-pressure chemical vapor deposition, and is patterned to form a second signal electrode. The second signal electrode may be a metal material such as copper, aluminum, cobalt, or a composite layer composed of molybdenum and copper, or a composite layer composed of molybdenum and aluminum.

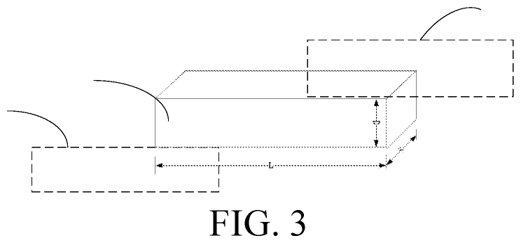

In some embodiments, the first signal electrode is one of a source or a drain, and the second signal electrode is the other one of the source or the drain. In FIG. 2, the first signal electrode 610 is a source, and the second signal electrode 620 is a drain. By forming the films of the first signal electrode 610 and the second signal electrode 620 separately, the channel length of the active layer 400 can be better controlled. FIG. 3 is a vertical structure adopted for the channel of the active layer 400. As shown in FIG. 3, the lower part of the active layer 400 is connected to the first signal electrode 610 and its upper part is connected to the second signal electrode. The thickness of the cube is D, and the cross-sectional area of the cube is obtained by cutting along the horizontal plane of the L direction. The length D of the cube represents the channel length, and the cross-sectional area D*S of the cube represents the channel width. The film thickness of the first signal electrode and the second signal electrode is the channel length of the active layer, which makes the channel length easier to control and reduces the adverse reactions of the array substrate.

In some embodiments, the etching barrier layer is formed with a through-hole, the through-hole penetrates the etching barrier layer and forms a contact area with the active layer, and the second signal electrode is connected to the active layer in the area through the through-hole.

In some embodiments, the array substrate further includes a pixel electrode 800 and an insulating layer 700. The insulating layer 700 is disposed on a side of the etching barrier layer 500 away from the substrate 100, the pixel electrode 800 is disposed on a side of the insulating layer 700 away from the substrate. The pixel electrode 800 is connected to the second signal electrode 620 through a through-hole penetrating the insulating layer 700.

In some embodiments, the insulating layer 700 includes an organic insulating layer 710, a common electrode 720 deposited on the organic insulating layer 710, a first inorganic insulating layer 730 deposited on the common electrode layer 720, a touch detection line 740 deposited on the first inorganic insulating layer 730, and the second inorganic layer 750 deposited on the touch detection line 740. A through-hole is provided on the first inorganic insulating layer 720, the through-hole penetrates the first inorganic insulating layer 720, and the touch detection line 730 is connected to the common electrode 720 through the through-hole. The common electrode 720 and the touch detection line 730 form a touch capacitor, the common electrode 720 forms a lower polar plate of the touch capacitor, and the touch detection line 730 forms an upper polar plate of the touch capacitor. A portion of the common electrode 720 connected to the touch detection line 730 forms a touch point. When a finger touches the display device, the capacitance near the touch point is changed to form an electric signal transmitted to a chip of the display device, and an operation position is recorded.

The material of the organic insulating layer 710 is a polymer, such as polyvinyl phenol and the like. The material of the first inorganic layer 710 is one or more of silicon nitride and silicon oxide. The materials of the first inorganic insulating layer 720 and the second inorganic insulating layer 750 may be the same or different. The second method is to add a third metal layer (touch metal layer) and its corresponding insulating protective layer. By patterning the third metal layer, it is connected to the touch detection chip and the common electrode. Since an organic insulating layer (JAS) is generally disposed above the data line, the thickness of the organic insulating layer generally exceeds 2 μm, so that the touch sensor connection line of the third metal layer can be arbitrarily crossed without worrying about parasitic capacitance with the data line. Therefore, the aperture ratio is higher than that of the touch sensor connection line and the data line are arranged in the same layer. In addition, the embedded touch (in-cell) not only realizes the touch function but also needs to realize the display function at the display time. Generally, the common electrode will be divided into blocks and disposed in the same layer, in a manner of time-division multiplexing. That is, in the display stage, the common electrode is loaded with a common electrode signal, and the connection line of the touch sensor is connected to the common electrode when touching. Generally, the connection lines and common electrodes of the touch sensor are arranged in different layers, and a protective layer is arranged between them and connected through a contact hole. In addition, the connection line of the touch sensor is connected to the touch detection chip, and the capacitance of the common electrode is sensed during touch to determine the touch position.

In some embodiments, the area where the pixel electrode 800 contacts the second signal electrode 620 covers the area where the second signal electrode 620 contacts the active layer 400.

In some embodiments, the thickness of the area of the second signal electrode 620 in contact with the active layer 400 is greater than the thickness of the non-contact electrode area.

Since the active layer 400 uses indium gallium zinc oxide and is in separate contact with the source 610 and the drain 620, the active layer 400 can form a corresponding vertical channel while having a higher carrier concentration, the carrier mobility of the active layer is improved, and thereby improving the performance of the array substrate. Under the effect of applied voltage, the thin film transistors of the array substrate will change. Assuming that the source voltage is 0 and the drain voltage is greater than 0, the source-drain voltage difference is greater than 0. When the gate voltage is less than 0, that is, the voltage difference between the gate and the source is less than 0, under an action of a negative electric field, the electrons in the active layer 400 close to the gate insulating layer 300 are expelled. Since the voltage difference between the source and drain is greater than 0, electrons accumulate on the surface of the active layer 400 due to the positive surface potential of the drain metal, and as the absolute value of the negative voltage between the gate 200 and the source 610 increases, the electrons between the active layer 400 and the gate are gradually expelled. Further increasing the absolute value of the negative voltage between the gate 200 and the source 610, the electrons of the active layer 400 are further expelled to the boundary of the etching barrier layer 500. When the negative voltage difference between the gate 200 and the drain 610 reaches a certain value, the electronic state density at the interface of the active layer 400 will disappear, and the body current and the channel current will basically disappear. At this time, the corresponding voltage difference between the gate 200 and the source 610 is an ideal off-state voltage. When the voltage difference between the gate 200 and the source 610 is less than the off-state voltage, under the combined effect of the voltage between the negative gate 200 and the source 610 and the positive source 610 and drain 620, the hole carriers are formed between the gate and the drain, hole accumulation occurs at the interface of the active layer 400, and a large current of holes is formed so that the current formed is more stable.

In some embodiments, the gate layer is patterned to form the gate 200 and the scan line, and the first signal electrode layer is patterned to form the source 610 and the data line. During operation of the array substrate, parasitic capacitance is likely generated between the gate 200 and the data line, and parasitic capacitance is likely generated between the gate line 200 and the pixel electrode 800. Since the source 610 and the data line are formed below the active layer 400, and the drain 620 is formed above the active layer 400, the distance between the gate 200 and the data line is reduced, thereby reducing the parasitic capacitance between the gate 200 and the data line. The distance between the gate and the pixel electrode is increased, thereby reducing the parasitic capacitance between the gate 200 and the pixel electrode 800. The distance between the data line and the pixel electrode 800 is increased, thereby reducing the parasitic capacitance between the data line and the pixel electrode 800, reducing the load of the gate signal and the data signal, and reducing signal delay.

The present application provides a display device including an array substrate and a touch chip. The array substrate includes a substrate; a gate layer formed on the substrate and patterned to form a gate; a first signal electrode layer formed on a side of the gate away from the substrate, and patterned to form a first signal electrode; an active layer formed on a side of the first signal electrode away from the gate layer; a second signal electrode layer formed on a side of the active layer away from the first signal electrode, and patterned to form a second signal electrode; an insulating layer provided on a side of the second signal electrode away from the substrate; and a pixel electrode provided on a side of the insulating layer away from the substrate; wherein the first signal electrode is one of a source or a drain, and the second signal electrode is the other one of the source or the drain.

In some embodiments, the insulating layer includes an organic insulating layer, and the common electrode is disposed on the organic insulating layer. The first inorganic insulating layer is disposed on the common electrode, and the touch detection line is disposed on the first inorganic insulating layer. The second inorganic insulating layer is disposed on the touch detection line, wherein the first inorganic insulating layer is formed with a through-hole, and the touch detection line is connected to the common electrode through the through-hole. The touch detection line is connected to the touch chip, the touch detection line forms the upper polar plate of the touch capacitor, and the common electrode forms the lower polar plate of the touch capacitor. When the human body touches the display device, the capacitance is changed. The touch detection line transmits an electrical signal to the touch chip, and the touch chip transmits an instruction after receiving the signal. Since the source and the drain are formed separately, the parasitic capacitance generated by the touch detection line is less affected.

The present application provides an array substrate and a display device. The array substrate includes a substrate, a gate layer, a first signal electrode layer, an active layer, a second signal electrode layer, an insulating layer, and a common electrode layer, which are stacked, wherein the first signal electrode layer is patterned to form a first signal electrode, the second signal electrode layer is patterned to form a second signal electrode, the first signal electrode is one of a source or a drain, and the second signal electrode is the other one of the source or the drain. In this application, a two-layer structure is formed by separately forming a source and a drain, and a thickness of the film layer between the source and the drain is equal to a channel length of the active layer. By controlling the thickness of the film layer between the source and the drain, the channel length is controlled, and the yield of the array substrate is improved.

According to the above embodiment, it is known that: The array substrate and the display device thereof provided by the embodiments of the present application have been described in detail above, and specific examples have been used to explain the principles and implementation of the present application. The descriptions of the embodiments are only used to help understand the technical solutions and core ideas of the present application. Those of ordinary skill in the art should understand: It can still modify the technical solutions described in the foregoing embodiments, or equivalently substitute some of the technical features. However, these modifications or substitutions do not deviate from the scope of the technical solutions of the embodiments of the present application.

What is claimed is:

1. An array substrate, comprising:
a substrate;
a gate layer formed on the substrate and patterned to form a gate;
a first signal electrode layer formed on a side of the gate away from the substrate, and patterned to form a first signal electrode;
an active layer formed on a side of the first signal electrode away from the gate layer; and
a second signal electrode layer formed on a side of the active layer away from the first signal electrode, and patterned to form a second signal electrode;
wherein the first signal electrode is one of a source or a drain, and the second signal electrode is the other one of the source or the drain.

2. The array substrate according to claim 1, wherein the array substrate further comprises an etching barrier layer, and the etching barrier layer is positioned between the active layer and the second signal electrode.

3. The array substrate according to claim 2, wherein a through-hole is formed in the etching barrier layer, the through-hole penetrates the etching barrier layer and forms a contact area with the active layer, and the second signal electrode is connected to the active layer in the contact area through the through-hole.

4. The array substrate according to claim 3, wherein the array substrate further comprises a pixel electrode and an insulating layer, the insulating layer is disposed on a side of the etching barrier layer away from the substrate, the pixel electrode is disposed on a side of the insulating layer away from the substrate, and the pixel electrode is connected to the second signal electrode through the through-hole penetrating the insulating layer.

5. The array substrate according to claim 4, wherein an area where the pixel electrode contacts the second signal electrode covers an area where the second signal electrode contacts the active layer.

6. The array substrate according to claim 5, wherein a thickness of the second signal electrode in the area where the second signal electrode contacts the active layer is greater than a thickness of the second signal electrode in a non-contact area.

7. The array substrate according to claim 1, wherein the active layer is formed directly on a side of the first signal electrode away from the substrate.

8. The array substrate according to claim 1, wherein a film layer thickness between the first signal electrode and the second signal electrode is equal to a channel length of the active layer.

9. The array substrate according to claim 1, wherein the first signal electrode layer is further patterned to form data lines.

10. The array substrate according to claim 1, wherein a thickness of the active layer is in a range of 100 nm to 500 nm.

11. A display device, comprising the array substrate of claim 1, the array substrate comprising:
the substrate;
the gate layer formed on the substrate and patterned to form the gate;
the first signal electrode layer formed on the side of the gate away from the substrate, and patterned to form the first signal electrode;
the active layer formed on the side of the first signal electrode away from the gate layer; and
the second signal electrode layer formed on the side of the active layer away from the first signal electrode, and patterned to form the second signal electrode;
wherein the first signal electrode is one of the source or the drain, and the second signal electrode is the other one of the source or the drain.

12. The display device according to claim 11, wherein the array substrate further comprises an etching barrier layer, and the etching barrier layer is positioned between the active layer and the second signal electrode.

13. The display device according to claim 12, wherein a through-hole is formed in the etching barrier layer, the through-hole penetrates the etching barrier layer and forms a contact area with the active layer, and the second signal electrode is connected to the active layer in the contact area through the through-hole.

14. The display device according to claim 13, wherein the array substrate further comprises a pixel electrode and an insulating layer, the insulating layer is disposed on a side of the etching barrier layer away from the substrate, the pixel electrode is disposed on a side of the insulating layer away from the substrate, and the pixel electrode is connected to the second signal electrode through the through-hole penetrating the insulating layer.

15. The display device according to claim 14, wherein an area where the pixel electrode contacts the second signal electrode covers an area where the second signal electrode contacts the active layer.

16. The display device according to claim 15, wherein a thickness of the second signal electrode in the area where the second signal electrode contacts the active layer is greater than a thickness of the second signal electrode in a non-contact area.

17. The display device according to claim 11, wherein the active layer is formed directly on a side of the first signal electrode away from the substrate.

18. The display device according to claim 11, wherein a film layer thickness between the first signal electrode and the second signal electrode is equal to a channel length of the active layer.

19. The display device according to claim 11, wherein the first signal electrode layer is further patterned to form data lines.

20. The display device according to claim 11, wherein a thickness of the active layer is in a range of 100 nm to 500 nm.
